(19) United States
(12) Patent Application Publication
(10) Pub. No.: US 2026/0349007 A1
(43) Pub. Date: Nov. 5, 2026

(54) PROBE HEAD, PROBE CARD, PROBE SYSTEM AND PROBE THEREOF, TESTING METHOD, AND TESTED DEVICE

(71) Applicant: MPI CORPORATION, CHU-PEI CITY (TW)

(72) Inventors: CHIN-TIEN YANG, CHU-PEI CITY (TW); YU-HAO CHEN, CHU-PEI CITY (TW); CHIN-YI TSAI, CHU-PEI CITY (TW)

(73) Assignee: MPI CORPORATION, CHU-PEI CITY (TW)

(21) Appl. No.: 19/665,646

(22) Filed: May 1, 2026

Related U.S. Application Data
(60) Provisional application No. 63/798,594, filed on May 2, 2025.

(51) Int. Cl. G01R 1/073; G01R 1/067; G01R 31/26

(52) U.S. Cl. CPC G01R 1/07314; G01R 1/06738; G01R 31/2601

(57) ABSTRACT

A probe head includes at least one guide plate, and a plurality of probes respectively inserted through a plurality of guide holes of the guide plate and including at least one probe pair. The probe pair is formed of two probes. The head portion and/or tail portion of each probe of the probe pair includes a reduced cross-section segment, and at least one adjacent segment adjacent to the reduced cross-section segment. The reduced cross-section segment is smaller in cross-sectional area than the adjacent segment, so that each probe of the probe pair includes at least one recess formed by the reduced cross-section segment. The reduced cross-section segment is at least partially located in the guide hole. Accordingly, impedance matching between the probe head as a whole and the device under test is effectively improved, return loss during transmission of test signals is reduced, and testing accuracy is ensured.

### BACKGROUND OF THE INVENTION

### 1. Field of the Invention

The present invention relates to testing of semiconductor wafers or packaged devices and more particularly, to a probe head, a probe card, a probe system, a probe thereof for testing, a testing method, and a tested device.

### 2. Description of the Related Art

A probe card is a tool for testing electrical properties of semiconductor wafers or packaged devices. Typically, a probe card at least includes a probe head, a space transformer disposed on the probe head, and a main circuit board (also referred to as a wiring substrate) disposed on the space transformer. The probe head may include a plurality of probes. Each of the probes is configured to contact an electronic device under test (also referred to as DUT) integrated in a semiconductor wafer, so as to test electrical performance of the electronic device under test.

In recent years, demands for high-frequency/high-speed testing of electronic devices under test have been increasing. As data transmission speeds in testing environments increase, e.g. from 100 Gbps to more than 200 Gbps, impedance matching between the probe head as a whole and the device under test has an increasingly significant influence on high-speed signal transmission. When there is an impedance mismatch along the test path, i.e., signal transmission path, return loss becomes a significant issue.

However, the probe head is not composed solely of electronic components, but includes nonelectronic components as well, such as probes and guide plates. Therefore, impedance matching design of the probe head needs to take mechanical properties of these non-electronic components into consideration. Therefore, compared with the space transformer and the wiring substrate (PCB), the impedance matching design of the probe head is more difficult because it involves different types of components and requires consideration of influence of mechanical structures in electrical design. In view of this, how to improve the impedance matching between the probe head as a whole and the electronic device under test is a technical problem that urgently needs to be solved in this technical field.

### SUMMARY OF THE INVENTION

Therefore, the present invention provides a probe head, which is directed to high-frequency/high-speed testing and can effectively improve the impedance matching between the probe head as a whole and the device under test, thereby reducing the return loss during transmission of test signals to ensure testing accuracy.

The probe head provided by the present invention is applied in a probe card for testing an electronic device under test. The probe head includes at least one guide plate and a plurality of probes. The guide plate includes a plurality of guide holes, and the plurality of probes are respectively inserted through the plurality of guide holes. Each probe includes a head portion, a tail portion, and a body portion connected between the head portion and the tail portion, and the head portion is configured to contact the electronic device under test. The plurality of probes include at least one probe pair. The probe pair is composed of two of the probes. The head portion and/or tail portion of each probe of the probe pair includes at least one reduced cross-section segment, and at least one adjacent segment adjacent to the reduced cross-section segment. The cross-sectional area of the reduced cross-section segment is smaller than the cross-sectional area of the adjacent segment, such that each of the probes of the probe pair includes at least one recess formed by the reduced cross-section segment. The reduced cross-section segment is at least partially located in the guide hole of the guide plate.

As a result, in the probe head provided by the present invention, each probe composing the probe pair, which may be, for example, but unlimited to, a differential pair, has a segment arranged in the guide hole of the guide plate and reduced in cross-sectional area when compared with other segments (at least compared with the adjacent segment). For the segments of the two probes composing the probe pair arranged in the guide holes of the guide plate, the smaller the cross-sectional area of the probes themselves, the greater the characteristic impedance of the segments of the two probes. Therefore, by means of forming the reduced cross-section segments on the probes and making the reduced cross-section segments at least partially located in the guide holes of the guide plate, the present invention can optimize the structural proportion and electromagnetic behavior between the probes and the guide plate, thereby improving the characteristic impedance performance in the segments. In this way, impedance fluctuation caused between the two probes by the guide plate can be effectively reduced, thereby reducing the return loss between the probe head as a whole and the electronic device under test, and further improving the impedance matching between the probe head, or even the probe card to which it belongs, as a whole and the electronic device under test. Therefore, the present invention can effectively improve reliability and accuracy of high-speed signal testing and improve overall efficiency performance of the probe card in high-frequency applications. Furthermore, through the above structural design, the present invention can still effectively control impedance between the probes even without specifically selecting a material with a low dielectric constant as the material of the guide plate. Such design can improve designing flexibility of the guide plate and the whole probe head, so that material selection and structural design of the guide plate are more flexible, and therefore the required electrical characteristics and mechanical strength can be all taken into account to achieve overall performance optimization.

Preferably, the at least one guide plate includes a lower guide plate. The head portion of each of the probes of the probe pair is inserted through the guide hole of the lower guide plate, and includes the reduced cross-section segment. Each of the reduced cross-section segments of the head portions is at least partially located in the guide hole of the lower guide plate.

As a result, in the probe head provided by the present invention, the segment of the head portion of each probe composing the probe pair arranged in the guide hole of the lower guide plate has reduced cross-sectional area. Since the probe head usually includes upper and lower guide plates respectively for insertion of the tail portion and the head portion, and the head portion will be slightly moved upward and downward during testing, the thickness of the lower guide plate is usually greater than the thickness of the upper guide plate. By forming the reduced cross-section segment on the head portion and arranging the reduced cross-section segment in the guide hole of the lower guide plate, the aforementioned effects achievable by the reduced cross-section segment can be further enhanced.

More preferably, the at least one guide plate further includes an upper guide plate. The tail portion of each of the probes of the probe pair is inserted through the guide hole of the upper guide plate, and includes the reduced cross-section segment. Each of the reduced cross-section segments of the tail portions is at least partially located in the guide hole of the upper guide plate.

As a result, in the probe head provided by the present invention, for each probe composing the probe pair, the segment of the head portion thereof arranged in the guide hole of the lower guide plate and the segment of the tail portion thereof arranged in the guide hole of the upper guide plate both have reduced cross-sectional area. That is, each of the probes of the probe pair includes two reduced cross-section segments respectively located in the guide hole of the upper guide plate and the guide hole of the lower guide plate. This can further enhance the aforementioned effects.

Preferably, the plurality of probes include at least one normal probe provided without the reduced cross-section segment. Compared with an air gap between the normal probe and the guide hole, in which the normal probe is located, an air gap between the reduced cross-section segment and the guide hole, in which the reduced cross-section segment is located, is larger. In this way, impedance variation caused by the guide plate to the two probes of the probe pair is relatively smaller. This effectively reduces the return loss during signal transmission, thereby enhancing the reliability and accuracy of high-frequency/high-speed testing.

Preferably, each of the probes is one of a straight probe and a pre-bent probe (for example, with a Cobra shape). The probe pair is a differential pair for transmitting a pair of differential signals.

As a result, the present invention can use vertical probes. The vertical probe extends approximately along a longitudinal extension axis, but the body portion thereof is bent so as to be capable of slight elastic deformation when the head portion contacts the electronic device under test. The vertical probe may be a straight probe that is linear in shape when it is made, and the body portion thereof is bent due to horizontal offset between the upper guide plate and the lower guide plate when installed in the upper guide plate and the lower guide plate. The vertical probe may be alternatively a pre-bent probe that is bent when it is made. The present invention can use straight probes or pre-bent probes according to usage requirements.

Preferably, the reduced cross-section segment is entirely located in the guide hole of the guide plate, thereby more effectively reducing the impedance fluctuation caused between the two probes of the probe pair by the guide plate and further enhancing the aforementioned effects achievable by the reduced cross-section segment.

Preferably, the at least one guide plate includes a lower guide plate. The head portion of each of the probes of the probe pair is inserted through the guide hole of the lower guide plate, and includes the reduced cross-section segment. Each of the reduced cross-section segments of the head portions extends from within the guide hole of the lower guide plate to a location below a lower surface of the lower guide plate.

During a testing process, after the head portions of the probes contact the electronic device under test, the probe head and the electronic device under test will be further relatively moved by a testing stroke, also referred to as overdrive, so as to further pressing the head portions against the electronic device under test. At this time, the head portions will be moved upward relative to the lower guide plate. Since the reduced cross-section segment extends below the lower surface of the lower guide plate, when the head portion is moved upward relative to the lower guide plate, the portion of the reduced cross-section segment originally located below the lower surface of the lower guide plate will enter the guide hole of the lower guide plate, such that there will be still a quite long part of the reduced cross-section segment in the guide hole of the lower guide plate, or even the part of the probe located in the guide hole of the lower guide plate may entirely belong to the reduced cross-section segment. This design maintains stable impedance control capability throughout the entire overdrive, thereby further enhancing the aforementioned effects achievable by the reduced cross-section segment.

More preferably, each of the reduced cross-section segments of the head portions extends downward from the lower surface of the lower guide plate for a length, and the length is substantially greater than or equal to a maximum amount of upward movement of each head portion relative to the lower guide plate during testing.

As a result, such length design can ensure that during the overdrive, the part of the head portion entering the guide hole from below the lower guide plate is completely belong to the reduced cross-section segment. That is, the segment of the head portion having a relatively larger cross-sectional area is prevented from entering the guide hole to cause problems such as compression of the inner wall of the guide hole or contact impedance variation. Therefore, such length design can further enhance consistency and repeatability of testing.

More preferably, after each of the head portions is upwardly moved relative to the lower guide plate for the maximum amount during testing the electronic device under test, only the reduced cross-section segment of each of the probes of the probe pair is located in the guide hole of the lower guide plate. In other words, only the reduced cross-section segment, but no other segment of the probe, is located in the guide hole of the lower guide plate. This design maintains stable impedance control capability throughout the entire overdrive, thereby further enhancing the aforementioned effects achievable by the reduced cross-section segment.

Preferably, the adjacent segment defines a central axis, and the recess formed by the reduced cross-section segment surrounds an entire circumference of the reduced cross-section segment around the central axis uniformly in depth.

As a result, the reduced cross-section segment has circular cross-sections, and thus has the circumference. The cross-sectional shapes of other segments of the probe may also be circular. That is, when compared with other segments of the probe (at least compared with the adjacent segment), the reduced cross-section segment is reduced in overall diameter in a coaxial manner such that the reduced cross-section segment is uniformly thinned along the entire circumference and remains coaxial with the adjacent segment. Such structure is applicable to the probe originally having a circular cross-sectional shape, and is convenient for forming the reduced cross-section segment by turning process to achieve the aforementioned effects achievable by the reduced cross-section segment.

Preferably, the reduced cross-section segment includes a smallest cross-section zone and a transition zone. The transition zone is gradually reduced in diameter in a continuous manner from the adjacent segment to the smallest cross-section zone, such that the transition zone has a tapered surface.

As a result, the reduced cross-section segment has a circular cross-sectional shape, and the diameter thereof is not abruptly reduced from the diameter of the adjacent segment to the smallest diameter, but is continuously reduced in the transition zone without an obvious step. That can alleviate the problem of reduction of the cross-sectional area of the reduced cross-section segment weakening the structural strength of the probe.

Preferably, the recess formed by the reduced cross-section segment is located only on one side of the reduced cross-section segment without circumferentially surrounding an outer contour of the reduced cross-section segment.

As a result, the cross-sectional shape of the reduced cross-section segment, which is also the shape of the outer contour, may be any shape. The cross-sectional shapes of other segments of the probe may be circular, rectangular, or other shapes. Compared with other segments of the probe (at least compared with the adjacent segment), the reduced cross-section segment is reduced in cross-sectional area on only one side, and can be formed by cutting a normal probe on a single side thereof, thereby achieving the aforementioned effects achievable by the reduced cross-section segment. Furthermore, since the reduced cross-section segment is reduced in cross-sectional area on only one side, the reduced cross-section segment is an asymmetric structure with respect to the central axis of the adjacent segment. That is, the central axis of the reduced cross-section segment is offset from the central axis of the adjacent segment, such that the two probes of the probe pair can be arranged in a way that the recesses formed by the reduced cross-section segments thereof face each other across the guide plate, and thereby the central axes of the reduced cross-section segments of the two probes are offset from the central axes of the adjacent segments in directions away from each other. That is, the pitch (i.e., center-to-center distance) between the reduced cross-section segments of the two probes is greater than the pitch between the adjacent segments of the two probes. This design can further increase the characteristic impedance of the reduced cross-section segments of the two probes arranged in the guide holes of the guide plate, thereby further enhancing the aforementioned effects achievable by the reduced cross-section segment.

Preferably, two recesses are formed by the same reduced cross-section segment, and the two recesses are respectively located on two opposite sides of the reduced cross-section segment and symmetrical to each other, such that the reduced cross-section segment has an elongated cross-section.

As a result, the cross-sectional shape of the reduced cross-section segment may be any shape. The cross-sectional shapes of other segments of the probe may be circular, rectangular, or other shapes. Compared with other segments of the probe (at least compared with the adjacent segment), the reduced cross-section segment is reduced in cross-sectional area on two opposite sides, and can be formed by symmetrically cutting on two opposite sides of a normal probe, thereby achieving the aforementioned effects achievable by the reduced cross-section segment. Since the reduced cross-section segment is reduced in cross-sectional area on two opposite sides, the cross-section thereof is elongated, which may be, for example, a shape having two flat sides and two arc ends, a rectangular shape, an elliptical shape, or other shapes apparently having a major axis and a minor axis.

Preferably, the recess formed by the reduced cross-section segment circumferentially surrounds an outer contour of the reduced cross-section segment uniformly in depth.

As a result, the cross-sectional shape of the reduced cross-section segment, which is also the shape of the outer contour, may be circular, elliptical, rectangular, or other non-circular shapes. The cross-sectional shapes of other segments of the probe may be the same shape with a larger size. That is, compared with other segments of the probe (at least compared with the adjacent segment), the reduced cross-section segment is uniformly thinned along the entire outer contour in a coaxial or equivalent-to-coaxial manner, thereby achieving the aforementioned effects achievable by the reduced cross-section segment.

Preferably, the reduced cross-section segment includes a smallest cross-section zone and a transition zone. The transition zone is gradually reduced in cross-sectional area in a continuous manner from the adjacent segment to the smallest cross-section zone.

As a result, the cross-sectional shape of the reduced cross-section segment may be any shape, and the cross-sectional area thereof is not abruptly reduced from the cross-sectional area of the adjacent segment to the smallest cross-sectional area, but is continuously reduced in the transition zone without an obvious step, thereby forming, for example, a conical shape, a tapered elliptical shape, or an asymmetric polygonal or other non-circular tapered structure. This design can alleviate the problem of reduction of the cross-sectional area of the reduced cross-section segment weakening the structural strength of the probe.

Preferably, the recesses of the two probes of the probe pair at least partially face each other across the guide plate.

As a result, in the condition that the reduced cross-section segment is reduced along the entire circumference or the entire outer contour, the two probes of the probe pair do not require a specific arrangement direction. As long as the height positions of the reduced cross-section segments of the two probes are approximately the same, the recesses formed by the reduced cross-section segments thereof will partially face each other across the guide plate in the guide holes. In the condition that the reduced cross-section segment is reduced on only one side, the two probes of the probe pair are arranged such that the recesses formed by the reduced cross-section segments thereof face each other across the guide plate. That is, the reduced cross-section segments of the two probes are reduced in directions away from each other, such that the pitch between the reduced cross-section segments of the two probes is greater than the pitch between the probes. This further increases the characteristic impedance of the reduced cross-section segments of the two probes arranged in the guide holes of the guide plate, thereby further enhancing the aforementioned effects achievable by the reduced cross-section segment.

The present invention further provides a probe card for use in a probe system to test an electronic device under test integrated in a semiconductor wafer. The probe card includes a main circuit board, a space transformer, and a probe head as described above. The main circuit board and the probe head are respectively disposed on two opposite sides of the space transformer, and the tail portions of the probes of the probe head are electrically connected to the space transformer.

As a result, the probe card uses the probe head as described above, and thereby can achieve effects thereof. The impedance matching between the probe head, or even the probe card, as a whole and the electronic device under test can be effectively improved, thereby reducing the return loss during transmission of test signals and ensuring accuracy of high-frequency/high-speed testing. Therefore, the probe card has good overall efficiency performance in high-frequency applications.

The present invention further provides a probe system for testing an electronic device under test integrated in a semiconductor wafer. The probe system includes a fixture configured to support the semiconductor wafer, a probe card as described above, and a test apparatus. The probe card is disposed on the test apparatus. The test apparatus is configured to be electrically connected with the electronic device under test through the probe card so as to perform electrical testing on the electronic device under test.

As a result, the probe system uses the probe card as described above, and thereby can achieve effects thereof. The impedance matching between the probe head, or even the probe card, as a whole and the electronic device under test can be effectively improved, thereby reducing the return loss during transmission of test signals and ensuring accuracy of high-frequency/high-speed testing. Therefore, the probe system has good overall efficiency performance in high-frequency applications.

The present invention further provides a probe for use in a probe card to test an electronic device under test. The probe includes a head portion, a tail portion, and a body portion connected between the head portion and the tail portion, and the head portion is configured to be inserted through a guide hole of a guide plate and to physically contact a contact pad of the electronic device under test during testing the electronic device under test. The head portion includes a reduced cross-section segment, and an adjacent segment adjacent to the reduced cross-section segment. The cross-sectional area of the reduced cross-section segment is smaller than the cross-sectional area of the adjacent segment, such that the head portion includes a recess formed by the reduced cross-section segment. The reduced cross-section segment is at least partially located in the guide hole.

As a result, the head portion of the probe has a segment arranged in the guide hole of the guide plate, that is reduced in cross-sectional area when compared with other segments (at least compared with the adjacent segment). This design can optimize the structural proportion and electromagnetic behavior between the probe and the guide plate, thereby improving the characteristic impedance performance of the segment of the probe disposed in the guide hole and further improving the impedance matching between the probe head, or even the probe card to which it belongs, as a whole and the electronic device under test.

Preferably, the adjacent segment defines a central axis, and the recess formed by the reduced cross-section segment circumferentially surrounds an outer contour of the reduced cross-section segment around the central axis.

As a result, the cross-sectional shape of the reduced cross-section segment, which is also the shape of the outer contour, may be circular, elliptical, rectangular, or other non-circular shapes. The cross-sectional shapes of other segments of the probe may be the same shape with a larger size. That is, compared with other segments of the probe (at least compared with the adjacent segment), the reduced cross-section segment is uniformly thinned along the entire outer contour in a coaxial or equivalent-to-coaxial manner, thereby achieving the aforementioned effects achievable by the reduced cross-section segment.

Preferably, the recess formed by the reduced cross-section segment is located only on one side of the reduced cross-section segment without circumferentially surrounding an outer contour of the reduced cross-section segment.

As a result, the cross-sectional shape of the reduced cross-section segment, which is also the shape of the outer contour, may be any shape. The cross-sectional shapes of other segments of the probe may be circular, rectangular, or other shapes. Compared with other segments of the probe (at least compared with the adjacent segment), the reduced cross-section segment is reduced in cross-sectional area on only one side, and can be formed by cutting a normal probe on a single side thereof, thereby achieving the aforementioned effects achievable by the reduced cross-section segment. Furthermore, since the reduced cross-section segment is reduced in cross-sectional area on only one side, when two probes compose a probe pair, the two probes can be arranged in a way that the pitch between the reduced cross-section segments is greater than the pitch between the two probes. This arrangement can further increase the characteristic impedance of the reduced cross-section segments of the two probes arranged in the guide holes of the guide plate, thereby further enhancing the aforementioned effects achievable by the reduced cross-section segment.

Preferably, the reduced cross-section segment includes a smallest cross-section zone and a transition zone. The transition zone is gradually reduced in cross-sectional area in a continuous manner from the adjacent segment to the smallest cross-section zone, such that the transition zone has a tapered surface.

As a result, the cross-sectional shape of the reduced cross-section segment may be any shape, and the cross-sectional area thereof is not abruptly reduced from the cross-sectional area of the adjacent segment to the smallest cross-sectional area, but is continuously reduced in the transition zone without an obvious step, thereby forming, for example, a conical shape, a tapered elliptical shape, or an asymmetric polygonal or other non-circular tapered structure. This design can alleviate the problem of the reduction of the cross-sectional area of the reduced cross-section segment weakening the structural strength of the probe.

Preferably, the cross-section of the reduced cross-section segment is non-circular.

As a result, the present invention is unlimited to forming the reduced cross-section segment by reducing the diameter of a probe originally having circular cross-sections in a coaxial manner, but may reduce the cross-sectional area of a probe originally having circular cross-sections on one side, two sides, or in other manners, or may reduce the cross-sectional area of a probe originally having non-circular cross-sections in various manners, thereby forming the reduced cross-section segment with non-circular cross-sections, such as elliptical, rectangular, or other directional cross-sections.

Preferably, the reduced cross-section segment extends to a portion of the probe exposed outside the guide plate during use.

As a result, during a testing process, when the head portion of the probe is moved relative to the guide plate, the portion of the reduced cross-section segment originally exposed outside the guide plate can enter the guide hole of the guide plate, such that there will be still a quite long part of the reduced cross-section segment in the guide hole of the guide plate, or even the part of the probe located in the guide hole of the guide plate may entirely belong to the reduced cross-section segment. That maintains stable impedance control capability throughout the entire overdrive, thereby further enhancing the aforementioned effects achievable by the reduced cross-section segment.

Preferably, the body portion of the probe includes a multilayer structure including a plurality of layers and at least one slot formed between the layers. A cross-section of the body portion has a width side and a thickness side. The slot extends through the body portion along a direction parallel to the thickness side. The layers are separated from each other along a direction parallel to the width side. The length of the thickness side is greater than or equal to the length of the width side.

As a result, the slot can reduce the rigidity of the body portion and thereby lower the contact force applied by the probe to the contact pad of the electronic device under test, so as to avoid damage to the contact pad caused by excessive contact force. In particular, for high-frequency and high-speed testing requirements, shorter probes are usually used to achieve good electrical transmission properties. However, shorter probes tend to have higher rigidity and contact force. In such case, the slot can be provided to reduce the contact force of the probe. In addition, the slot also increases the elasticity of the body portion, ensuring the elastically curved deformation effect of the body portion along the direction of the width side. Furthermore, the length of the thickness side of the body portion is greater than or equal to the length of the width side. That is, the width of the body portion is not greater than its thickness, or even smaller than its thickness. That allows the body portion to exhibit better elastic deformation effect of being curved along the direction of the width side, and provides the body portion with a sufficient thickness to reduce the likelihood of breakage.

The present invention further provides a probe head for use in a probe card to test an electronic device under test. The probe head includes at least one guide plate, and a plurality of probes. The guide plate includes a plurality of guide holes. The plurality of probes are respectively inserted through the plurality of guide holes. Each probe includes a head portion, a tail portion, and a body portion connected between the head portion and the tail portion. The plurality of probes include at least one reduced cross-section probe and at least one normal probe. The reduced cross-section probe includes a reduced cross-section segment located in the guide hole. The cross-sectional area of the reduced cross-section segment is smaller than the cross-sectional area of an in-hole portion of the normal probe located in the guide hole, such that an air gap between the reduced cross-section segment of the reduced cross-section probe and the guide hole, in which the reduced cross-section segment is located, is larger than an air gap between the in-hole portion of the normal probe and the guide hole, in which the in-hole portion is located.

As a result, in the probe head provided by the present invention, some of the probes (i.e., the reduced cross-section probe) have a segment (i.e., the reduced cross-section segment) disposed in the guide hole of the guide plate, that is reduced in cross-sectional area when compared with a portion (i.e., the in-hole portion) of others of the probes (i.e., the normal probe) disposed in the guide hole of the guide plate. Accordingly, the structural proportion and electromagnetic behavior between the reduced cross-section probe and the guide plate can be optimized, and therefore the characteristic impedance performance within the segment can be improved. This arrangement can effectively reduce the impedance fluctuation caused by the guide plate on the reduced cross-section probe, thereby reducing the return loss between the probe head as a whole and the electronic device under test, and further improving the impedance matching between the probe head, or even the probe card to which it belongs, as a whole and the electronic device under test. Therefore, the present invention can effectively improve reliability and accuracy of high-speed signal testing, and improve overall efficiency performance of the probe card in high-frequency applications. Furthermore, through the above structural design, the present invention can still effectively control the impedance between the probes even without specifically selecting a material having a low relative dielectric constant as the material of the guide plate. Such design can improve the designing flexibility of the guide plate and the whole probe head, such that material selection and structural design of the guide plate are more flexible, and the required electrical characteristics and mechanical strength can be all taken into account to achieve overall performance optimization.

The present invention further provides a testing method for testing an electronic device under test integrated in a semiconductor wafer. The testing method includes:
providing the probe system as described above;
positioning the probe card to face the electronic device under test; and
making the probes of the probe card contact the electronic device under test and testing an electrical property of the electronic device under test.

The present invention further provides a tested device. The tested device is a device that has been tested by the aforementioned testing method.

As a result, the testing method uses the probe system as described above, and therefore can achieve effects of the probe system as described above, effectively improving the impedance matching between the probe head, or even the probe card, as a whole and the electronic device under test, reducing the return loss during transmission of test signals, and ensuring accuracy of high-frequency/high-speed testing, thereby having good overall efficiency performance in high-frequency applications.

Further scope of applicability of the present invention will become apparent from the detailed description given hereinafter. However, it should be understood that the detailed description and specific examples, while indicating preferred embodiments of the invention, are given by way of illustration only, since various changes and modifications within the scope of the invention will become apparent to those skilled in the art from this detailed description.

### BRIEF DESCRIPTION OF THE DRAWINGS

The present invention will become more fully understood from the detailed description given herein below and the accompanying drawings which are given by way of illustration only, and thus are not limitative of the present invention, and wherein:

FIG. 1 is a schematic view of a probe system according to a first preferred embodiment of the present invention;

FIGS. 2 and 3 are schematic sectional views of a probe head of the probe system;

FIG. 4 is approximately similar to FIG. 3, but further showing a normal probe;

FIG. 5 is a schematic sectional view taken along the line 5-5 in FIG. 3;

FIGS. 6 and 7 are similar to FIG. 5, but showing different configurations of reduced cross-section segments;

FIG. 8 is similar to FIG. 3, but the reduced cross-section segments of the probes in FIG. 8 correspond to the configuration shown in FIG. 6;

FIG. 9 is a schematic sectional view of a probe head according to a second preferred embodiment of the present invention;

FIG. 10 is a schematic sectional view taken along the line 10-10 in FIG. 9;

FIGS. 11 and 12 are similar to FIG. 10, but showing different configurations of reduced cross-section segments;

FIG. 13 is similar to FIG. 9, but the reduced cross-section segments of the probes in FIG. 13 correspond to the configuration shown in FIG. 11;

FIG. 14 is a schematic sectional view of a probe head according to a third preferred embodiment of the present invention;

FIG. 15 is a schematic sectional view taken along the line 15-15 in FIG. 14; and

FIGS. 16 and 17 are approximately enlarged views of a part of FIG. 2, but showing different configurations of reduced cross-section segments.

### DETAILED DESCRIPTION OF THE INVENTION

First of all, it is to be mentioned that same or similar reference numerals used in the following embodiments and the appendix drawings designate same or similar elements or the structural features thereof throughout the specification for the purpose of concise illustration of the present invention. It should be noticed that for the convenience of illustration, the components and the structure shown in the figures are not drawn according to the real scale and amount, and the features mentioned in each embodiment can be applied in the other embodiments if the application is possible in practice. Besides, when it is mentioned that an element is disposed on another element, it means that the former element is directly disposed on the latter element, or the former element is indirectly disposed on the latter element through one or more other elements between aforesaid former and latter elements. When it is mentioned that an element is directly disposed on another element, it means that no other element is disposed between aforesaid former and latter elements.

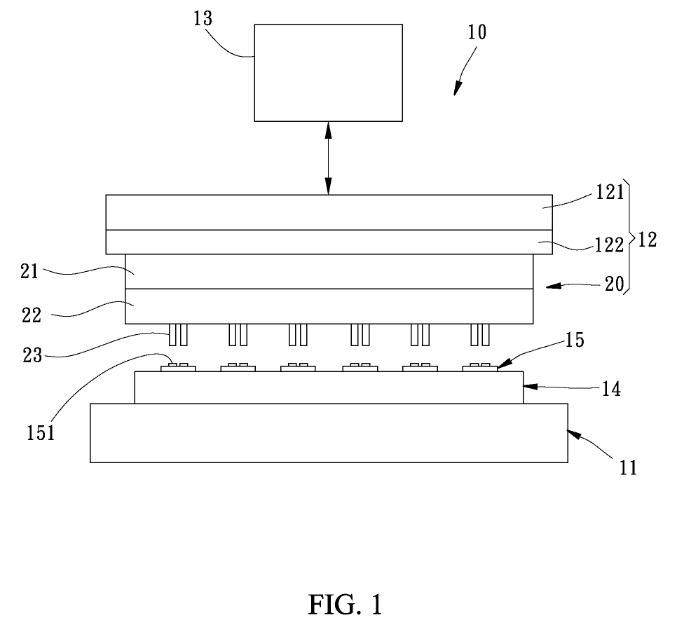

Referring to FIG. 1, a probe system 10 according to a first preferred embodiment of the present invention includes a fixture 11, a probe card 12, and a test apparatus 13. The fixture 11 is configured to support a semiconductor wafer 14, and a plurality of electronic devices under test 15 are formed on the semiconductor wafer 14. Each of the electronic devices under test 15 includes a plurality of contact pads 151. The probe card 12 is disposed on the test apparatus 13, and the test apparatus 13 is configured to be electrically connected with the electronic devices under test 15 through the probe card 12 so as to test electrical properties of the electronic devices under test 15.

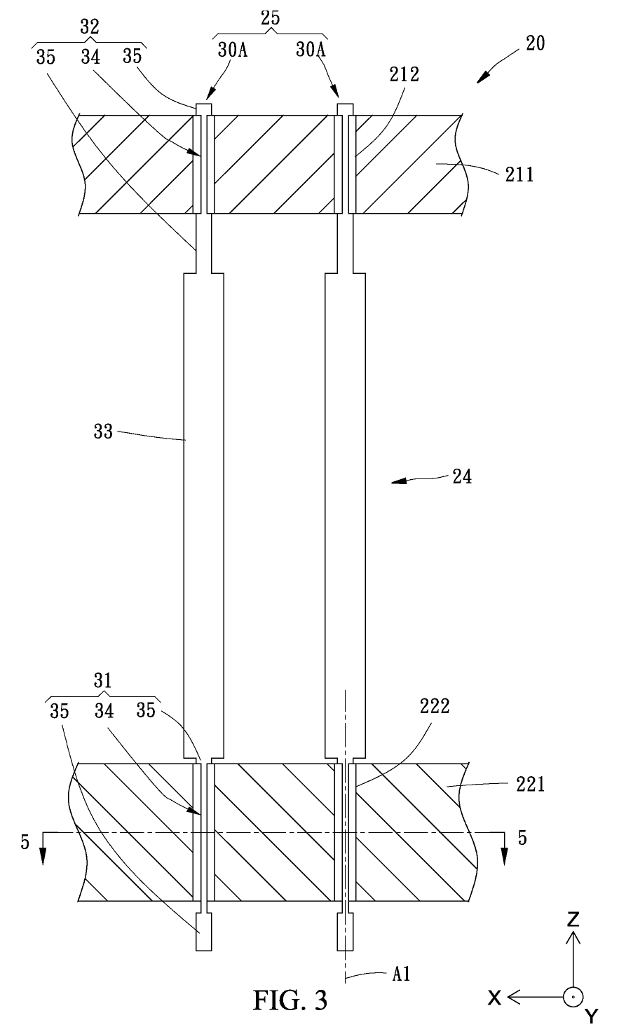

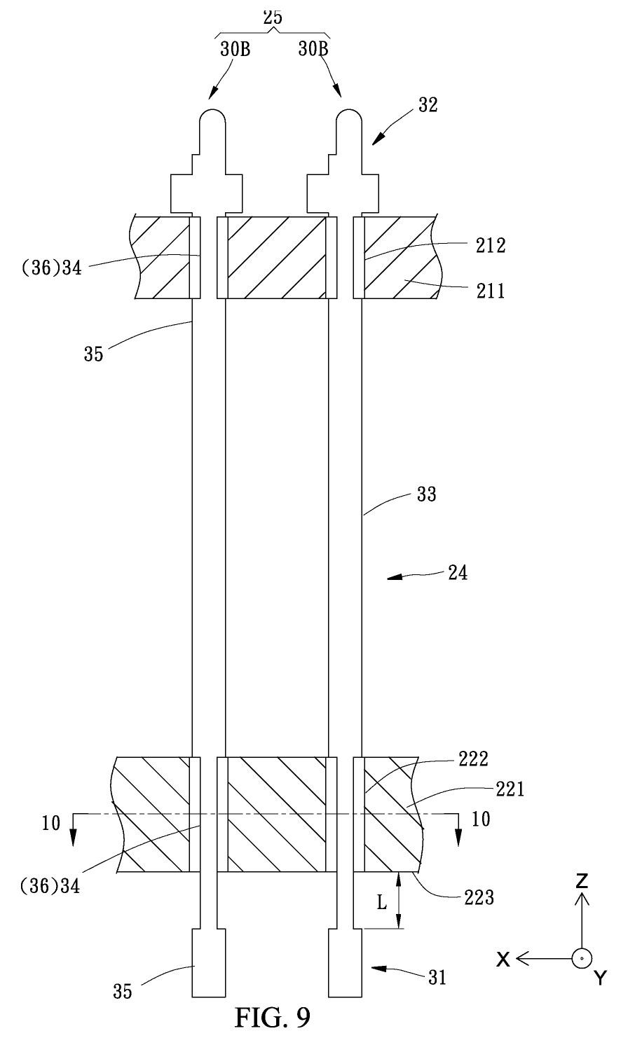

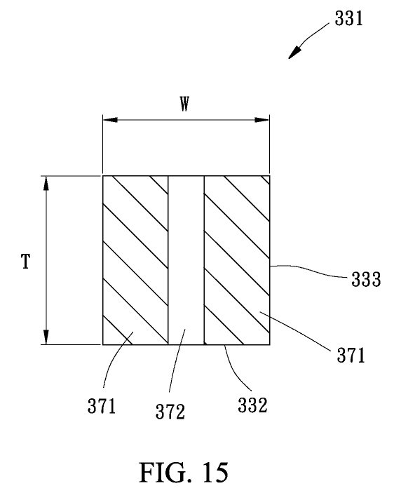

The probe card 12 includes a main circuit board 121, a space transformer 122, and a probe head 20. The main circuit board 121 and the probe head 20 are respectively disposed on two opposite sides of the space transformer 122. The probe head 20 includes an upper guide plate unit 21, a lower guide plate unit 22, and a plurality of probes 23 inserted in the upper guide plate unit 21 and the lower guide plate unit 22. The probes 23 used in the present invention may be pre-bent probes, such as the probes 30A and the normal probe 30A’ in the first preferred embodiment as shown in FIG. 4. Alternatively, the probes 23 used in the present invention may be straight probes, such as the probes 30B and 30C in second and third preferred embodiments as shown in FIGS. 9 and 14. The structures of the probes will be described in detail below.

Referring to FIGS. 1-3, the probe head 20 in the present invention includes at least one guide plate. In this embodiment, the at least one guide plate includes an upper guide plate 211 of the upper guide plate unit 21, and a lower guide plate 221 of the lower guide plate unit 22. The upper guide plate 211 includes a plurality of guide holes 212. The lower guide plate 221 includes a plurality of guide holes 222. The upper guide plate unit 21 may include a plurality of upper guide plates 211 stacked on one another. The lower guide plate unit 22 may include a plurality of lower guide plates 221 stacked on one another. The upper guide plate unit 21 and the lower guide plate unit 22 may be provided on edges thereof with protruding structures, and the protruding structures are directly connected to each other. Alternatively, a hollow middle guide plate (not shown) may be connected between the upper guide plate unit 21 and the lower guide plate unit 22.

The various probes 30A, 30B, 30C and normal probe 30A’ in the present invention each include a head portion 31 located at one end thereof, a tail portion 32 located at the other end thereof, and a body portion 33 connected between the head portion 31 and the tail portion 32. The head portion 31 is inserted through the guide hole 222 of the lower guide plate 221, and extends to a location below a lower surface 223 of the lower guide plate 221 for physically contacting the contact pad 151 of the electronic device under test 15. The tail portion 32 is inserted through the guide hole 212 of the upper guide plate 211 for being abutted against a contact pad (not shown) on a lower surface of the space transformer 122 so as to be electrically connected to the space transformer 122, such that the probes 30A, 30B, 30C and the normal probe 30A’ are electrically connected to the test apparatus 13 through the space transformer 122 and the main circuit board 121. Through the probe card 12, the test apparatus 13 provides test signals to the electronic device under test 15 and/or receives result signals from the electronic device under test 15, so as to test the electronic device under test 15. The body portion 33 is located between the upper guide plate unit 21 and the lower guide plate unit 22, and the body portion 33 is typically designed to be capable of slight elastic deformation when the head portion 31 contacts the contact pad 151 of the electronic device under test 15, which will be described in detail below.

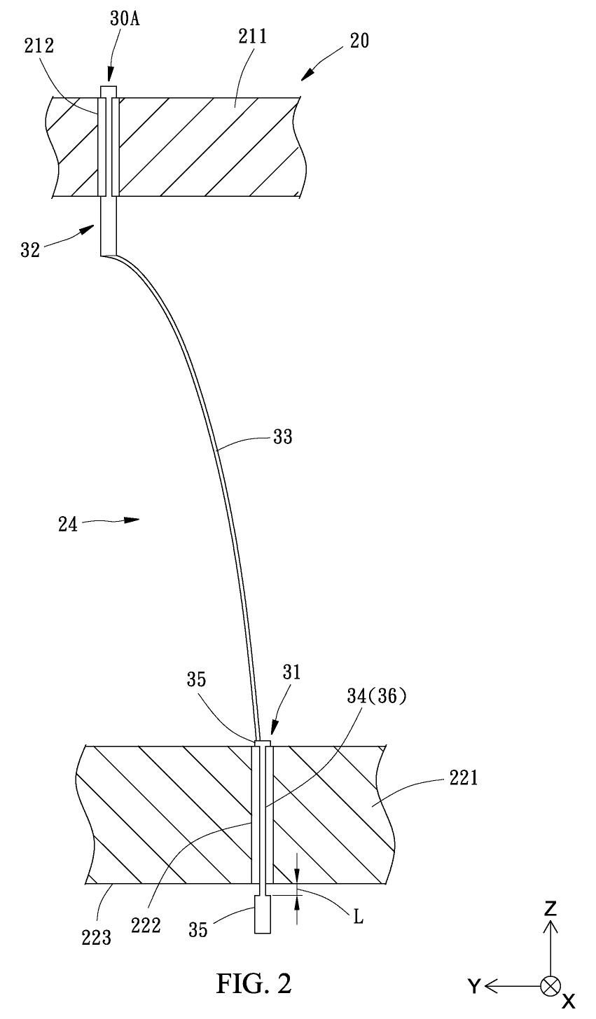

It should be noted that the body portions 33 of the two probes 30A shown in FIG. 3 are curved as shown in FIG. 2 when viewed along the X-axis, and the two probes 30A are arranged along the X-axis. Therefore, only one of the probes 30A is shown in FIG. 2. The probe head shown in FIG. 9 is in a state that the upper guide plate unit 21 and the lower guide plate unit 22 have not yet been horizontally offset relative to each other in a horizontal direction, i.e., in the X-axis and/or Y-axis direction. At this time, the body portions 33 of the two probes 30B are straight, and therefore the shape of the probes 30B when viewed along the X-axis is not illustrated.

In the present invention, for the simplification of illustration, all figures only show a part of a plurality of vertical probes typically included in one probe head 20. In practice, the vertical probes are arranged according to the layout and quantity of the contact pads 151 of the electronic device under test 15, and typically arranged in a central region of the probe head 20 The vertical probes refer to probes having an elongated shape and extending approximately along a vertical axis (Z-axis) when applied in a probe card, but are unlimited to extending exactly in a straight line along the vertical axis. The probes applicable to the present invention may at least include straight probes or pre-bent probes. The straight probes may be, for example, forming wires (also referred to as FW) or microelectromechanical wires (also referred to as MEMS wire or MW). The pre-bent probes may be, for example, cobra probes or microelectromechanical body portion pre-bent probes. In addition, appropriate configurations of the probes themselves (e.g., pre-bent probes) or the guide plate, through which the probes (e.g., straight probes such as forming wires or MEMS wires) are inserted, may assist the probes in bending within a space 24 inside the guide plate, as shown in FIG. 2. Specifically, the straight probes refer to probes that are linear when the manufacture thereof is finished, such as the probes 30B and 30C in the second and third preferred embodiments. The bending of the body portions 33 thereof is caused by horizontal offset of the upper guide plate unit 21 and the lower guide plate unit 22 when the probes are installed in the upper guide plate unit 21 and the lower guide plate unit 22. The figures of the second and third preferred embodiments show the state that the upper guide plate unit 21 and the lower guide plate unit 22 have not yet been horizontally offset and the body portions 33 have not yet been bent. The pre-bent probes refer to probes that are already bent when the manufacture thereof is finished, such as the probes 30A and the normal probe 30A’ in the first preferred embodiment. The body portions 33 thereof are originally bent, and do not require to be bent by the horizontal offset of the upper guide plate unit 21 and the lower guide plate unit 22.

When the probe head 20 is of the so-called offset plate type, which can use straight probes such as forming wires or MEMS wires, like the probes 30B and 30C in the second and third preferred embodiments, specifically speaking, the centers of the corresponding guide holes 212 and 222 of the upper and lower guide plates 211 and 221 for the same probe to be inserted therethrough may be offset from each other. In other words, the centerline connecting the corresponding guide holes 212 and 222 is not parallel to the vertical axis. The vertical axis may be the Z-axis in the local coordinate system of the figures, which is perpendicular to a reference plane. The reference plane may correspond to a horizontal extension plane of the guide plates. Accordingly, the probes accommodated in the guide holes 212 and 222 of the upper and lower guide plates 211 and 221 are deformed relative to a longitudinal extension axis thereof, which corresponds to the Z-axis in the local reference system, and the longitudinal extension axis is oriented perpendicularly to the reference plane. The upper and lower guide plates 211 and 221 may be parallel to each other and extend along the reference plane. The semiconductor wafer 14, the electronic device under test 15, and the space transformer 122 may also extend along the reference plane. When the probes in the probe head 20 are of the pre-bent type, such as the cobra probes in the first preferred embodiment, each probe has a pre-deformed configuration, in which an offset is present between the head portion 31 and the tail portion 32, that has been defined in placement conditions of the probe head. In such case, the probe includes a pre-deformed part that assists in providing appropriate bending to the probe, even when the probe is not in contact with the electronic device under test 15. The probe further undergoes deformation during operation, specifically, when pressure is applied as it makes contact with the electronic device under test 15. It should be noted that for proper probe head function, the probes should have a proper axial mobility within the guide holes. This design enables individual probe replacement in the event of probe failure without necessitating replacement of the entire probe head. The axial mobility of the probes, particularly for sliding within the guide holes, contrasts with the general safety requirement during operation of the probe head.

In the process that the aforementioned various probes 30A, 30B, 30C and the normal probe 30A’ are used to test the electronic device under test 15, after the head portions 31 contact the contact pads 151 of the electronic device under test 15, the probe card 12 and the fixture 11 will be further relatively moved toward each other by a testing stroke (also referred to as overdrive, OD, overtravel, or OT), such that the head portions 31 are moved upward relative to the guide plate by the overdrive and pressed against the contact pads 151 of the electronic device under test 15, and the body portions 33 are compressed and undergo buckling deformation.

In addition, it should be emphasized that the probes in the present invention may have cross-sections of different shapes. Specifically, in the first preferred embodiment, the head portions 31 and the tail portions 32 of the probes 30A and the normal probe 30A’ are originally cylindrical. That is, the cross-sections thereof are originally circular. The probes 30A are subsequently formed with at least one reduced cross-section segment 34 by cutting, which will be described in detail below. The body portions 33 of the probes 30A and the normal probe 30A’ in the first preferred embodiment are in a curved plate shape, and the cross-sections thereof are approximately rectangular. In the second and third preferred embodiments, each segment of the probes 30B and 30C is originally in a square prism shape. That is, the cross-sections thereof are square. They are subsequently formed with at least one reduced cross-section segment 34 by cutting, which will be described in detail below. The aforementioned cross-sections are unlimited to being circular or square, but may be rectangular, elliptical, triangular, any polygonal shape, or any shape. Considering that the probes are usually polished on an abrasive cloth to make end portions thereof rounded, such as uppermost ends of the tail portions in the second and third preferred embodiments, the cross-sections of the probes are preferably circular or square, because these shapes are relatively easier to be polished into rounded shapes. Those having ordinary skill in the art should understand that cross-sections of the actually manufactured probes may still have certain tolerances or manufacturing errors, and therefore may not be geometrically perfect in the above shapes.

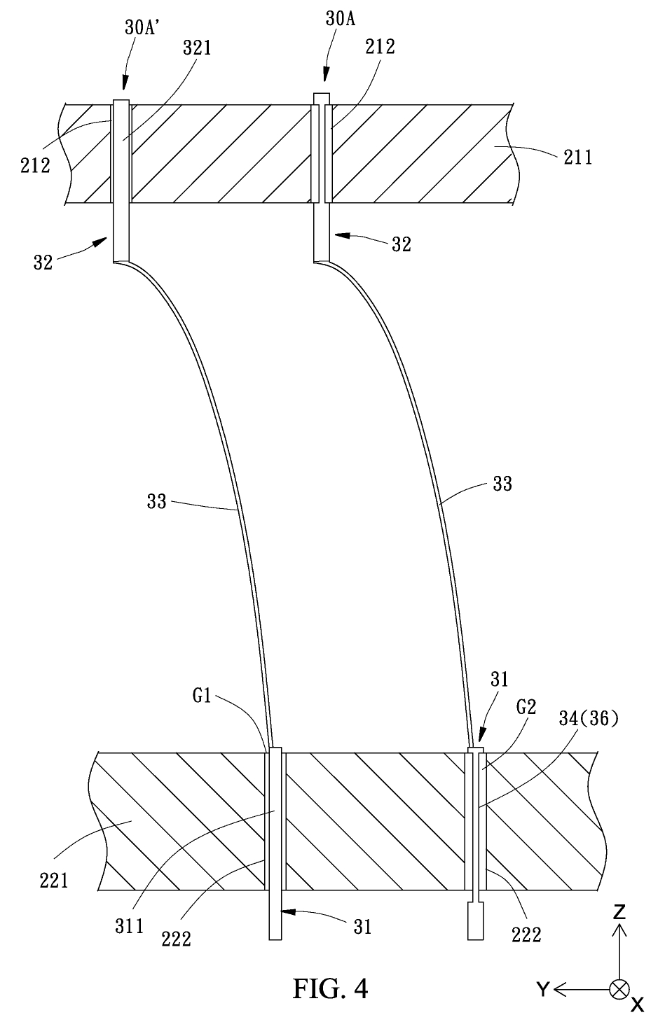

In this embodiment, the plurality of probes of the probe head 20 include at least one probe pair 25. Each probe pair 25 may be used to transmit a pair of differential signals, which means the probe pair 25 is a differential pair. In a preferred embodiment of the present invention, the differential pair is used to transmit differential signals. That is, two single-ended signal lines (for example, referred to as a P line and an N line) are respectively connected to two connection points (i.e., TX+ and RX+ described below) and connected to two other connection points (i.e., TX− and RX− described below), so as to simultaneously transmit signals having the same signal voltage amplitude but opposite signal phases. That is, one signal is positive and the other is negative. In other words, the two signal lines are referenced to each other. The P line references the N line, the N line references the P line, and they ideally serve as mutual reference loops. The differential pair is connected to a transmitting end (generally referred to as TX) and a receiving end (generally referred to as RX) of the electronic device under test 15. The transmitting end (TX) includes two connection points (generally referred to as TX+ and TX−). The receiving end (RX) also includes two connection points (generally referred to as RX+ and RX−). The transmitting end (TX) is connected to a high-frequency signal source. The receiving end (RX) is connected to an error detector. As shown in FIG. 3, in the first preferred embodiment, two probes 30A constitute one probe pair 25. The head portion 31 and the tail portion 32 of each probe 30A each include a reduced cross-section segment 34, and two adjacent segments 35 respectively adjacent to upper and lower ends of the reduced cross-section segment 34. More specifically, the adjacent segment 35 at the upper end of the head portion 31 is adjacent to the body portion 33, but such adjacent segment 35 may be omitted, or such adjacent segment 35 may be the body portion 33. The adjacent segment 35 at the lower end of the head portion 31 is a contact end portion for contacting the contact pad 151 of the electronic device under test 15. Similarly, the adjacent segment 35 at the lower end of the tail portion 32 is adjacent to the body portion 33, but such adjacent segment 35 may be omitted, or such adjacent segment 35 may be the body portion 33. The adjacent segment 35 at the upper end of the tail portion 32 is a contact end portion for contacting the contact pad of the space transformer 122. The cross-sectional area of each reduced cross-section segment 34 is smaller than the cross-sectional area of the adjacent segment 35 adjacent thereto, such that each probe 30A includes at least one recess 36 formed by the reduced cross-section segment 34, as shown in FIGS. 4 and 5. In addition, the reduced cross-section segment 34 is at least partially located in the guide hole of the guide plate. That is, the reduced cross-section segment 34 of the head portion 31 may be entirely located in the guide hole 222 of the lower guide plate 221, or may be partially exposed outside the guide hole 222, and the reduced cross-section segment 34 of the tail portion 32 may be entirely located in the guide hole 212 of the upper guide plate 211, or may be partially exposed outside the guide hole 212. In the figures of the present invention, the reduction extent of the reduced cross-section segment 34 is illustrated in a relatively exaggerated manner. In practice, the diameter or length of the cross-section 343 of the reduced cross-section segment 34 is approximately reduced to 50% to 95% of the diameter or length of the cross-section of the adjacent segment 35, preferably 70% to 90%.

The recess 36 mentioned in the present invention refers to a space formed by inward recessing of the reduced cross-section segment 34 from an outer surface of the probe toward a center thereof. Further speaking, the plurality of probes of the probe head 20 may include not only the probes 30A composing the probe pair 25, but also at least one normal probe 30A’ provided without the reduced cross-section segment, as shown in FIG. 4. The probe 30A may be formed from a normal probe 30A’ by cutting to form the reduced cross-section segment 34. The probe having the reduced cross-section segment 34 is also referred to as a reduced cross-section probe in the present invention. Since the probe 30A has the space formed by the reduced cross-section segment 34, i.e. the recess 36, as compared with the air gaps G1 between the head portion 31 and the tail portion 32 of the normal probe 30A’ and the guide holes 222, 212 in which they are located, the air gaps G2 between the reduced cross-section segments 34 and the guide holes 222, 212 in which they are located is larger, such that the impedance variation caused by the guide plate to the two probes 30A of the probe pair 25 is smaller. More specifically, the head portion 31 and the tail portion 32 of the normal probe 30A’ respectively include in-hole portions 311, 321 located in the guide holes 222, 212. The cross-sectional areas of the reduced cross-section segments 34 of the reduced cross-section probe is smaller than the cross-sectional areas of the in-hole portions 311, 321 of the normal probe 30A’, such that the air gaps G2 are larger than the air gaps G1.

Specifically speaking, for the portions of the two probes composing the probe pair disposed in the guide holes of the guide plate, the smaller the cross-sectional area of the probes themselves is, and/or the larger the pitch between the two probes is, the greater the characteristic impedance of the portions of the two probes in the guide holes of the guide plate will be. Therefore, the present invention forms the reduced cross-section segment 34 on the probe 30A and allows the reduced cross-section segment 34 to be at least partially located in the guide hole of the guide plate, so as to optimize the structural proportion and electromagnetic behavior between the probes 30A and the guide plate, thereby improving the characteristic impedance performance of the portions of the probes 30A in the guide holes of the guide plate. This design can effectively reduce the impedance fluctuation caused between the probes 30A by the guide plate, thereby reducing the return loss between the probe head 20 as a whole and the electronic device under test 15, and further improving the impedance matching between the probe head 20, or even the probe card 12, as a whole and the electronic device under test 15. Therefore, the present invention can effectively improve reliability and accuracy of high-speed signal testing, and improve overall efficiency performance of the probe card 12 in high-frequency applications. Furthermore, through the above structural design, the present invention can still effectively control the impedance between the probes even without specifically selecting a material having a low dielectric constant as the material of the guide plate. Such design can improve the designing flexibility of the guide plate and the whole probe head, such that material selection and structural design of the guide plate are more flexible, and therefore the required electrical characteristics and mechanical strength can be all taken into account to achieve overall performance optimization.

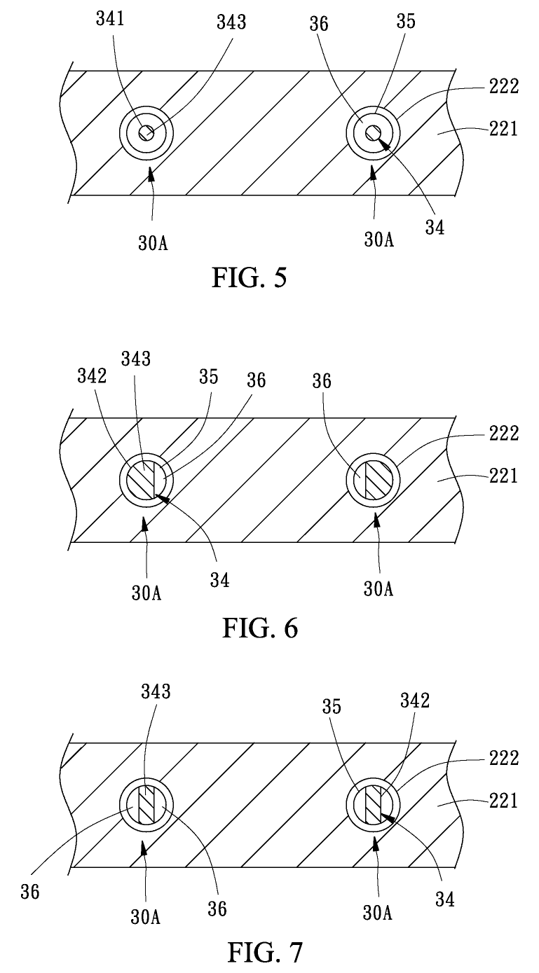

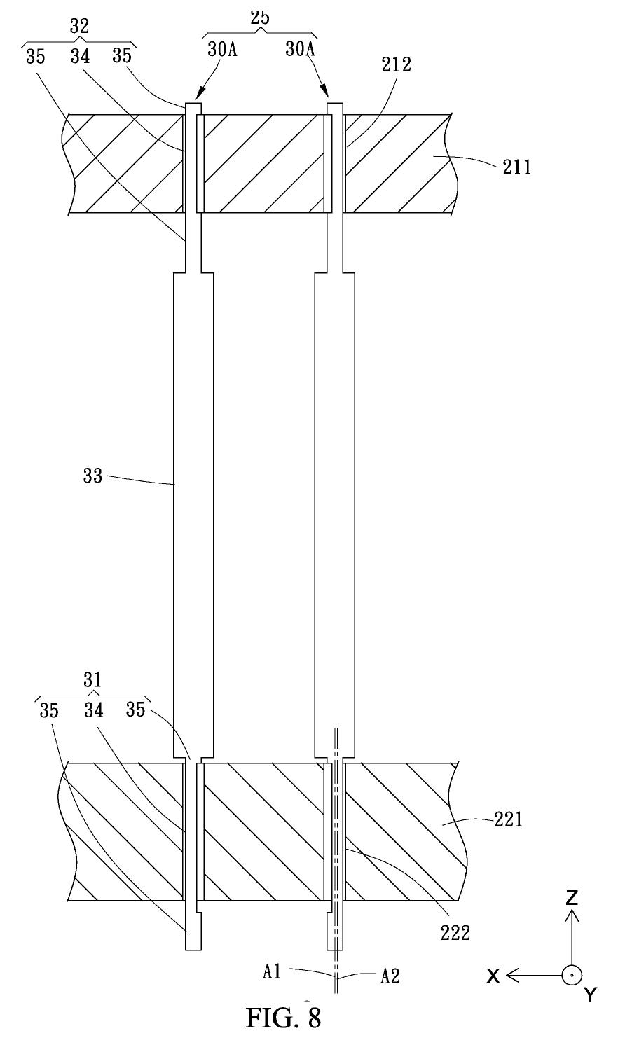

In the configuration shown in FIGS. 2-5, the reduced cross-section segment 34 is reduced in overall diameter in a coaxial manner, such that the reduced cross-section segment 34 is uniformly thinned along an entire circumference and remains coaxial with the adjacent segments 35. Specifically, the adjacent segments 35 define a central axis A1 as shown in FIG. 3, and the recess 36 formed by the reduced cross-section segment 34 surrounds an entire circumference 341 (as shown in FIG. 5) of the reduced cross-section segment 34 around the central axis A1 uniformly in depth. That is, the recess 36 has the same depth at various angular positions thereof. However, the reduced cross-section segment 34 may be not uniformly thinned along the entire circumference. For example, in the configuration shown in FIGS. 6 and 8, the reduced cross-section segment 34 is reduced in cross-sectional area only on one side thereof. For example, a normal probe 30A’ may be processed by cutting on a single side thereof to become the probe 30A. Therefore, the recess 36 formed by the reduced cross-section segment 34 is located only on one side of the reduced cross-section segment 34 without circumferentially surrounding an outer contour 342 of the reduced cross-section segment 34. For another example, in the configuration shown in FIG. 7, the reduced cross-section segment 34 is reduced in cross-sectional area on two opposite sides thereof. For example, a normal probe 30A’ may be processed by cutting on two opposite sides thereof to become the probe 30A. Therefore, two recesses 36 are formed by the same reduced cross-section segment 34, and the two recesses 36 are respectively located on two opposite sides of the reduced cross-section segment 34 and symmetrical to each other, such that the reduced cross-section segment 34 has an elongated cross-section 343.

Further speaking, in the configuration shown in FIGS. 6 and 8, the reduced cross-section segment 34 is reduced in cross-sectional area only on one side, and therefore, the reduced cross-section segment 34 is an asymmetric structure with respect to the central axis A1 of the adjacent segments 35. That is, the central axis A2 of the reduced cross-section segment 34 is offset from the central axis A1 of the adjacent segment 35. In addition, the two probes 30A are arranged such that the recesses 36 formed by the reduced cross-section segments 34 of the two probes 30A face each other across the guide plate, and thereby the central axes A2 of the reduced cross-section segments 34 of the two probes 30A are offset from the central axes A1 of the adjacent segments 35 in directions away from each other. That is, the pitch between the reduced cross-section segments 34 of the two probes 30A is greater than the pitch between the adjacent segments 35 of the two probes 30A. This arrangement can further increase the characteristic impedance of the reduced cross-section segments 34 of the two probes 30A disposed in the guide holes of the guide plate, thereby further enhancing the aforementioned effects achievable by the reduced cross-section segment 34. The recess 36 formed by the reduced cross-section segment 34 forms a radial dimensional reduction along the X-axis, such that the transverse cross-sectional area of the reduced cross-section segment 34 is smaller than the transverse cross-sectional area of the adjacent segment 35. In addition, when the probe card is actually assembled, the reduced cross-section segments 34 are abutted against the guide holes 212, 222 along the Y-axis. Therefore, the reduction direction of the recess 36 formed by the reduced cross-section segment 34 is perpendicular to the abutting direction of the reduced cross-section segment 34 in the guide hole.

Furthermore, as shown in FIG. 2, the reduced cross-section segment 34 of the head portion 31 of the probe 30A is not only located in the guide hole 222 of the lower guide plate 221, but also extends downward from a lower surface 223 of the lower guide plate 221 for a length L. The length L is substantially greater than or equal to the maximum amount of upward movement of the head portion 31 relative to the lower guide plate 221 during testing, i.e., the aforementioned overdrive. In addition, after the head portion 31 is moved upward relative to the lower guide plate 221 for the maximum amount during testing, only the reduced cross-section segment 34 of the probe 30A is located in the guide hole 222 of the lower guide plate 221. That is, only the reduced cross-section segment 34, but no other segment of the probe 30A, is located in the guide hole 222 of the lower guide plate 221. This arrangement maintains stable impedance control capability throughout the entire overdrive, thereby further enhancing the aforementioned effects achievable by the reduced cross-section segment 34.

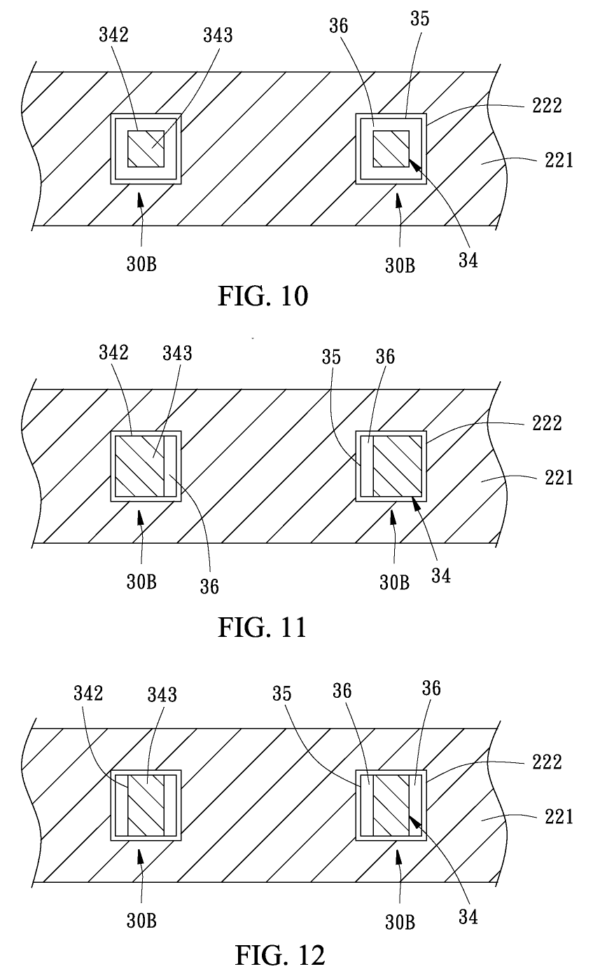

Referring to FIGS. 9 and 10, a second preferred embodiment of the present invention is similar to the first preferred embodiment, except that straight probes are used in this embodiment, and cross-sections thereof are square. It should be noted that FIGS. 9 and 10 show the state that the upper guide plate 211 and the lower guide plate 221 have not yet been relatively offset. For example, they have not yet been offset along the X-axis, or have not yet been offset along both the X-axis and the Y-axis. The two probes 30B in FIGS. 9 and 10 constitute one probe pair 25, such as a differential pair. The head portion 31 and the tail portion 32 of each probe 30B are both provided with a reduced cross-section segment 34, and recesses 36 formed by the reduced cross-section segments 34 circumferentially surround outer contours 342 of the reduced cross-section segments 34 uniformly in depth. Therefore, the outer contours 342 of the reduced cross-section segments 34 are also square. Other structural features and effects of this embodiment are similar to those of the first preferred embodiment, thereby not be repeated hereinafter.

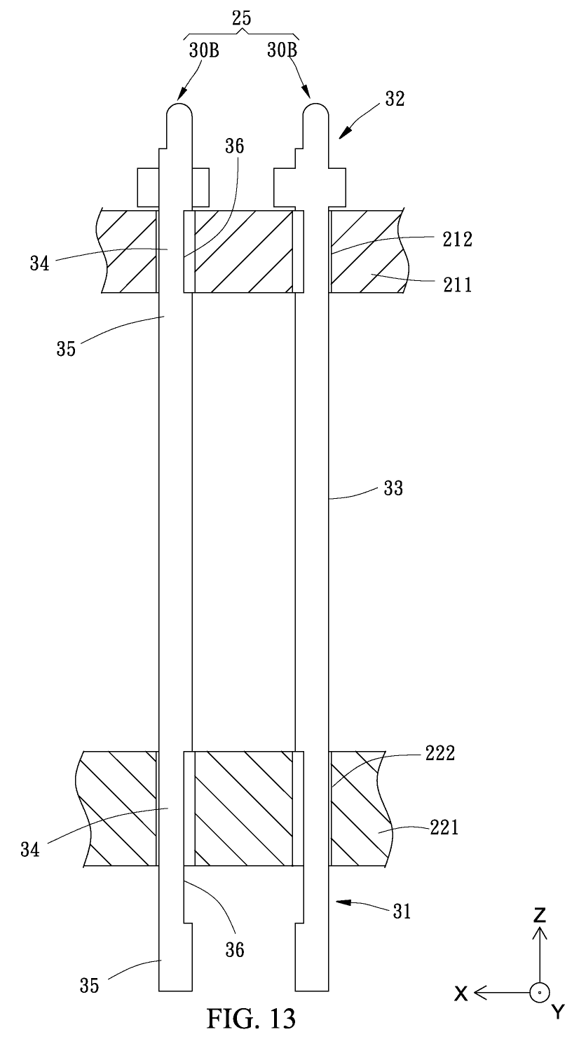

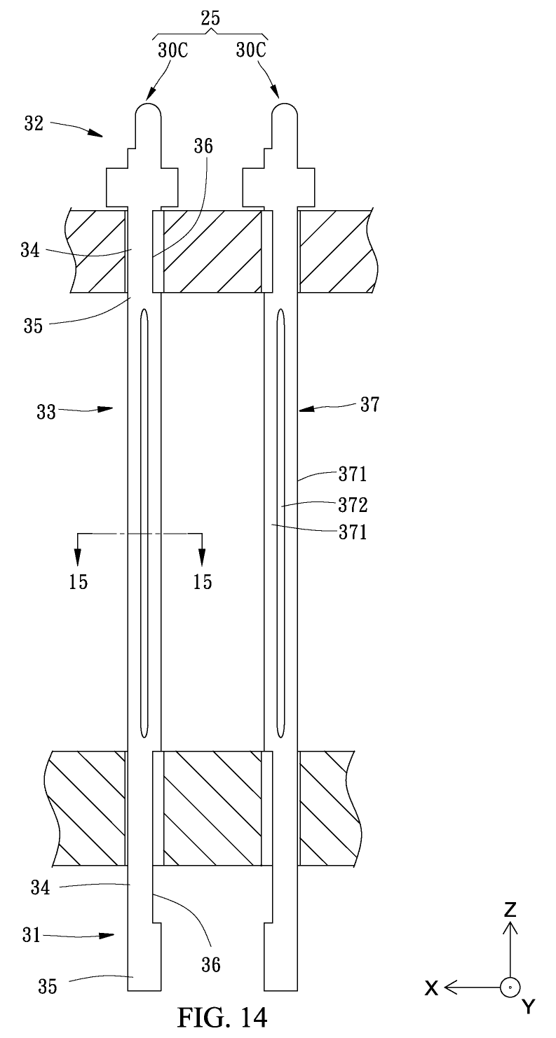

The reduced cross-section segment 34 in the second preferred embodiment may be not uniformly thinned along the entire outer contour thereof. For example, in the configuration shown in FIGS. 11 and 13, the reduced cross-section segment 34 is reduced in cross-sectional area only on one side thereof. Therefore, the recess 36 formed by the reduced cross-section segment 34 is located only on one side of the reduced cross-section segment 34 without circumferentially surrounding the outer contour 342 of the reduced cross-section segment 34. The recess 36 formed by the reduced cross-section segment 34 form a radial dimensional reduction along the X-axis, such that the transverse cross-sectional area of the reduced cross-section segment 34 is smaller than the transverse cross-sectional area of the adjacent segment 35. In addition, when the probe card is actually assembled, the reduced cross-section segments 34 are abutted against the guide holes 212, 222 along the Y-axis. Therefore, the reduction direction of the recesses 36 formed by the reduced cross-section segments 34 is perpendicular to the abutting direction of the reduced cross-section segments 34 in the guide holes. For another example, in the configuration shown in FIG. 12, the reduced cross-section segment 34 is reduced in cross-sectional area on two opposite sides thereof. Therefore, two recesses 36 are formed by the same reduced cross-section segment 34, and the two recesses 36 are respectively located on two opposite sides of the reduced cross-section segment 34 and symmetrical to each other, such that the reduced cross-section segment 34 has an elongated cross-section 343. In fact, in the present invention, the recess 36 of the reduced cross-section segment 34 may surround the entire circumference, be provided on one side, be provided on two opposite sides, or be provided on three sides or four sides, or have other variations.

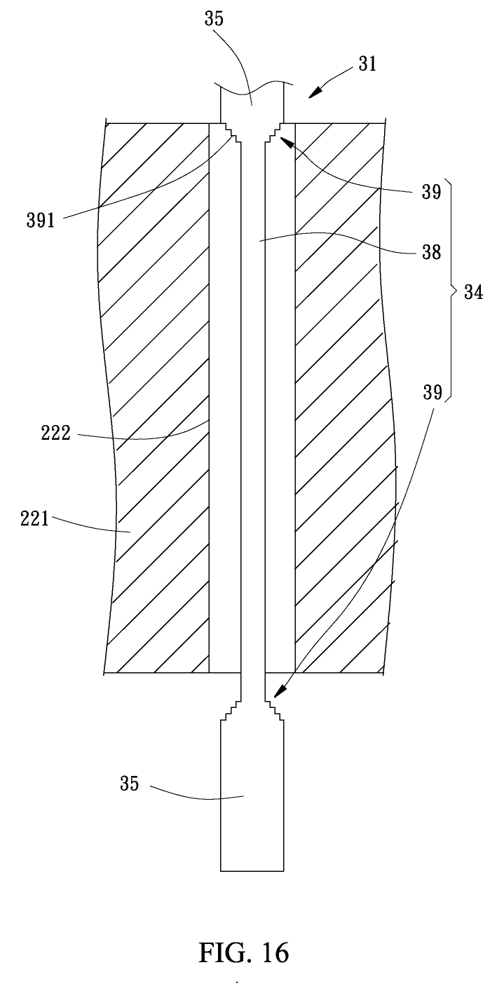

Referring to FIG. 14, a third preferred embodiment of the present invention is similar to the second preferred embodiment, except that in this embodiment the body portion 33 of the probe 30C includes a multilayer structure 37. The multilayer structure 37 includes a plurality of layers 371, and at least one slot 372 formed between the layers 371. As shown in FIG. 15, a cross-section 331 of the body portion 33 has a width side 332 and a thickness side 333. The slot 372 extends through the body portion 33 along a direction parallel to the thickness side 333 (i.e., along the Y-axis), and extends in an elongated shape along a longitudinal direction of the body portion 33 so that when the body portion 33 is not yet bent and deformed, the slot 372 extends along the vertical axis (Z-axis). In addition, the layers 371 are separated from each other along a direction parallel to the width side 332 (i.e., along the X-axis). Such slot 372 can weaken rigidity of the body portion 33 so as to reduce the contact force of the probe, thereby preventing the contact pad 151 of the electronic device under test 15 from being damaged due to excessive contact force of the probe. Furthermore, the body portion 33 originally extends linearly along the Z-axis. When the upper guide plate unit 21 and the lower guide plate unit 22 are offset relative to each other along the X-axis, the body portion 33 bends along the X-axis to present a curved shape on an X-Z plane. When the head portion 31 contacts the electronic device under test 15 and is thereby subjected to a force, the body portion 33 can be further elastically bent along the X-axis. The aforementioned slot 372 can improve elasticity of bending of the body portion 33 along the X-axis, thereby ensuring the elastic deformation effect of the body portion 33 along the X-axis. In addition, the length of the thickness side 333 of the body portion 33, i.e. thickness T, is greater than or equal to the length of the width side 332, i.e. width W. That brings the body portion 33 relatively better elastic deformation effect, and makes the body portion 33 have sufficient thickness T so as to be less likely to break.

In each above embodiment, each reduced cross-section segment 34 may be formed in a gradually reducing manner. The head portion 31 of the pre-bent probe in the first preferred embodiment is taken as an example for description below, and the reduced cross-section segment 34 at any portion of any type of probe may adopt a similar design.

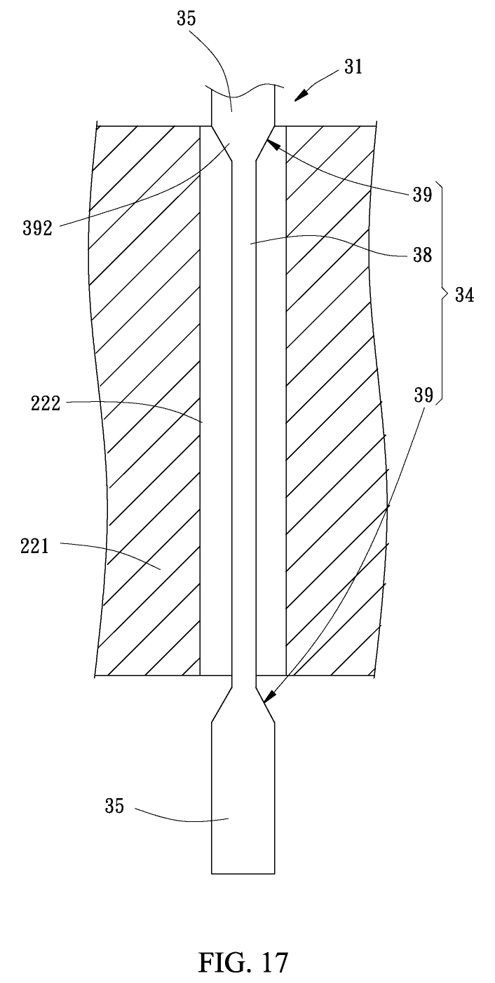

As shown in FIG. 16, the reduced cross-section segment 34 may include a smallest cross-section zone 38 and at least one transition zone 39. The transition zone 39 is reduced in diameter from the adjacent segment 35 to the smallest cross-section zone 38 in a stepwise manner, such that the transition zone 39 has a stepwise surface 391 in which diameter changes are clearly identifiable. In the case that the cross-section of the reduced cross-section segment 34 is non-circular, the transition zone 39 can still be reduced in cross-sectional area from the adjacent segment 35 to the smallest cross-section zone 38 in a stepwise manner and produce the stepwise surface 391. As a result, the cross-sectional area of the reduced cross-section segment 34 is not abruptly reduced from the cross-sectional area of the adjacent segment 35 to the smallest cross-sectional area, but is reduced stepwise within the transition zone 39. That can alleviate the problem of reduction of the cross-sectional area of the reduced cross-section segment 34 weakening the structural strength of the probe.

Alternatively, as shown in FIG. 17, the reduced cross-section segment 34 may include a smallest cross-section zone 38 and a transition zone 39. The transition zone 39 is continuously reduced in diameter from the adjacent segment 35 to the smallest cross-section zone 38, such that the transition zone 39 has a tapered surface 392. In the case that the cross-section of the reduced cross-section segment 34 is non-circular, the transition zone 39 can still be continuously reduced in cross-sectional area from the adjacent segment 35 to the smallest cross-section zone 38 and form an inclined plane or a curved surface similar to a tapered shape. As a result, the cross-sectional area of the reduced cross-section segment 34 is not abruptly reduced from the cross-sectional area of the adjacent segment 35 to the smallest cross-sectional area, but is continuously reduced within the transition zone 39 without an obvious step. That can alleviate the problem of reduction of the cross-sectional area of the reduced cross-section segment 34 weakening the structural strength of the probe.

The invention being thus described, it will be obvious that the same may be varied in many ways. Such variations are not to be regarded as a departure from the scope of the invention, and all such modifications as would be obvious to one skilled in the art are intended to be included within the scope of the following claims.

For example, the present invention is unlimited to differential signal applications. In other embodiments, the probe pair may be used to transmit single-ended signals. In a single-ended signal arrangement, a signal line transmits signal through only one signal probe (e.g. S), and uses a neighboring ground probe (e.g. G) as a reference loop, such as in a GS or GSG structure. In this case, the signal line is referenced to a ground terminal (GND), rather than being referenced to another signal line as in differential signal arrangement. The single-ended signal may be connected to a single signal connection point of a transmitting end (TX) or a receiving end (RX) of the electronic device under test 15.

What is claimed is:

1. A probe head for use in a probe card to test an electronic device under test, the probe head comprising:
at least one guide plate, the guide plate comprising a plurality of guide holes; and
a plurality of probes respectively inserted through the guide holes, each of the probes comprising a head portion, a tail portion, and a body portion connected between the head portion and the tail portion, the head portion being configured to contact the electronic device under test;
wherein the plurality of probes comprise at least one probe pair; the probe pair is composed of two of the probes; at least one of the head portion and the tail portion of each of the probes of the probe pair comprises a reduced cross-section segment, and at least one adjacent segment adjacent to the reduced cross-section segment; a cross-sectional area of the reduced cross-section segment is smaller than a cross-sectional area of the adjacent segment so that each of the probes of the probe pair comprises at least one recess formed by the reduced cross-section segment; the reduced cross-section segment is at least partially located in the guide hole of the guide plate.

2. The probe head as claimed in claim 1, wherein the at least one guide plate comprises a lower guide plate; the head portion of each of the probes of the probe pair is inserted through the guide hole of the lower guide plate, and comprises the reduced cross-section segment; each of the reduced cross-section segments of the head portions is at least partially located in the guide hole of the lower guide plate.

3. The probe head as claimed in claim 2, wherein the at least one guide plate further comprises an upper guide plate; the tail portion of each of the probes of the probe pair is inserted through the guide hole of the upper guide plate, and comprises the reduced cross-section segment; each of the reduced cross-section segments of the tail portions is at least partially located in the guide hole of the upper guide plate.

4. The probe head as claimed in claim 1, wherein the plurality of probes comprise at least one normal probe provided without the reduced cross-section segment; compared with an air gap between the normal probe and the guide hole, in which the normal probe is located, an air gap between the reduced cross-section segment and the guide hole, in which the reduced cross-section segment is located, is larger.

5. The probe head as claimed in claim 1, wherein each of the probes is one of a straight probe and a pre-bent probe; the probe pair is a differential pair for transmitting a pair of differential signals.

6. The probe head as claimed in claim 1, wherein the reduced cross-section segment is entirely located in the guide hole of the guide plate.

7. The probe head as claimed in claim 1, wherein the at least one guide plate comprises a lower guide plate; the head portion of each of the probes of the probe pair is inserted through the guide hole of the lower guide plate, and comprises the reduced cross-section segment; each of the reduced cross-section segments of the head portions extends from within the guide hole of the lower guide plate to a location below a lower surface of the lower guide plate.

8. The probe head as claimed in claim 7, wherein each of the reduced cross-section segments of the head portions extends downwardly from the lower surface of the lower guide plate for a length; the length is substantially greater than or equal to a maximum amount of upward movement of each of the head portions relative to the lower guide plate during testing the electronic device under test.

9. The probe head as claimed in claim 8, wherein after each of the head portions is upwardly moved relative to the lower guide plate for the maximum amount during testing the electronic device under test, only the reduced cross-section segment of each of the probes of the probe pair is located in the guide hole of the lower guide plate.

10. The probe head as claimed in claim 1, wherein the adjacent segment defines a central axis; the recess formed by the reduced cross-section segment surrounds an entire circumference of the reduced cross-section segment around the central axis uniformly in depth.

11. The probe head as claimed in claim 1, wherein the reduced cross-section segment comprises a smallest cross-section zone and a transition zone; the transition zone is gradually reduced in diameter in a continuous manner from the adjacent segment to the smallest cross-section zone so that the transition zone has a tapered surface.

12. The probe head as claimed in claim 1, wherein the recess formed by the reduced cross-section segment is located on only one side of the reduced cross-section segment without circumferentially surrounding an outer contour of the reduced cross-section segment.

13. The probe head as claimed in claim 1, wherein two said recesses are formed by the same reduced cross-section segment; the two recesses are respectively located on two opposite sides of the reduced cross-section segment and symmetrical to each other, such that the reduced cross-section segment has an elongated cross-section.

14. The probe head as claimed in claim 1, wherein the recess formed by the reduced cross-section segment circumferentially surrounds an outer contour of the reduced cross-section segment uniformly in depth.

15. The probe head as claimed in claim 1, wherein the reduced cross-section segment comprises a smallest cross-section zone and a transition zone; the transition zone is gradually reduced in cross-sectional area in a continuous manner from the adjacent segment to the smallest cross-section zone.

16. The probe head as claimed in claim 1, wherein the recesses of the two probes of the probe pair at least partially face each other across the guide plate.

17. A probe card for use in a probe system to test an electronic device under test integrated in a semiconductor wafer, the probe card comprising:
a main circuit board;
a space transformer; and
the probe head as claimed in claim 1;
wherein the main circuit board and the probe head are respectively disposed on two opposite sides of the space transformer, and the tail portion of each of the probes of the probe head is electrically connected to the space transformer.

18. A probe system for testing an electronic device under test integrated in a semiconductor wafer, the probe system comprising:
a fixture configured to support the semiconductor wafer;
the probe card as claimed in claim 17; and
a test apparatus;
wherein the probe card is disposed on the test apparatus, and the test apparatus is configured to be electrically connected with the electronic device under test through the probe card so as to test an electrical property of the electronic device under test.

19. A probe for use in a probe card to test an electronic device under test, the probe comprising a head portion, a tail portion, and a body portion connected between the head portion and the tail portion, the head portion being configured to be inserted through a guide hole of a guide plate and to physically contact a contact pad of the electronic device under test during testing the electronic device under test;
wherein the head portion comprises a reduced cross-section segment, and an adjacent segment adjacent to the reduced cross-section segment; a cross-sectional area of the reduced cross-section segment is smaller than a cross-sectional area of the adjacent segment, such that the head portion comprises a recess formed by the reduced cross-section segment; the reduced cross-section segment is at least partially located in the guide hole.

20. The probe as claimed in claim 19, wherein the adjacent segment defines a central axis, and the recess formed by the reduced cross-section segment circumferentially surrounds an outer contour of the reduced cross-section segment around the central axis.

21. The probe as claimed in claim 19, wherein the recess formed by the reduced cross-section segment is located only on one side of the reduced cross-section segment without circumferentially surrounding an outer contour of the reduced cross-section segment.

22. The probe as claimed in claim 19, wherein the reduced cross-section segment comprises a smallest cross-section zone and a transition zone; the transition zone is gradually reduced in cross-sectional area in a continuous manner from the adjacent segment to the smallest cross-section zone so that the transition zone has a tapered surface.

23. The probe as claimed in claim 19, wherein a cross-section of the reduced cross-section segment is non-circular.

24. The probe as claimed in claim 19, wherein the reduced cross-section segment extends to a portion of the probe exposed outside the guide plate during use.

25. The probe as claimed in claim 19, wherein the body portion comprises a multilayer structure; the multilayer structure comprises a plurality of layers, and at least one slot formed between the layers; a cross-section of the body portion has a width side and a thickness side; the slot extends through the body portion along a direction parallel to the thickness side; the layers are separated from each other along a direction parallel to the width side; a length of the thickness side is greater than or equal to a length of the width side.

26. A probe head for use in a probe card to test an electronic device under test, the probe head comprising:
at least one guide plate, the guide plate comprising a plurality of guide holes; and
a plurality of probes respectively inserted through the guide holes, each of the probes comprising a head portion, a tail portion, and a body portion connected between the head portion and the tail portion;
wherein the plurality of probes comprise at least one reduced cross-section probe and at least one normal probe; the reduced cross-section probe comprises a reduced cross-section segment located in the guide hole; a cross-sectional area of the reduced cross-section segment is smaller than a cross-sectional area of an in-hole portion of the normal probe located in the guide hole, such that an air gap between the reduced cross-section segment of the reduced cross-section probe and the guide hole, in which the reduced cross-section segment is located, is larger than an air gap between the in-hole portion of the normal probe and the guide hole, in which the in-hole portion is located.

27. A testing method for testing an electronic device under test integrated in a semiconductor wafer, the testing method comprising:
providing the probe system as claimed in claim 18;
positioning the probe card to face the electronic device under test; and
making the probes of the probe card contact the electronic device under test, and testing an electrical property of the electronic device under test.

28. A tested device, the tested device being a device that has been tested by the testing method as claimed in claim 27.
